(19) United States
(12) Patent Application Publication
(10) Pub. No.: US 2002/0182824 A1
(43) Pub. Date: Dec. 5, 2002

(54) Method of forming shallow trench isolation

(75) Inventors: Ying-Jen Lin, Hsinchu (TW); Joe Ko, Hsinchu (TW); Gary Hong, Hsinchu (TW); Yen-Lin Ding, Hsinchu (TW)

Correspondence Address: CHARLES C.H. WU, 7700 IRVINE CENTER DRIVE, SUITE 710, IRVINE, CA, 92618-3043, US

(73) Assignee: UNITED MICROELECTRONICS CORP.

(21) Appl. No.: 09/875,389

(22) Filed: Jun. 5, 2001

(51) Int. Cl. H01L 21/76

(52) U.S. Cl. 438/424

(57) ABSTRACT

A method of forming shallow trench isolation (STI) uses a flowable insulating layer. In the method, a pad oxide layer is first formed on a substrate. A stop layer is formed on the pad oxide layer. Then, a trench is formed in the stop layer, the pad oxide layer and the substrate. A liner oxide layer is formed on the inner surface of the trench. Thereafter, a flowable insulating layer, such as a doped silicon oxide layer, is formed in the trench. An insulating layer, such as a silicon oxide layer, is formed on the flowable insulating layer. Finally, the stop layer and the pad oxide layer are removed so as to completely form shallow trench isolation.

### BACKGROUND OF THE INVENTION

1. Field of the Invention

The invention relates to a method of forming ICs, and more particularly to a method of forming shallow trench isolation (STI).

2. Description of the Related Art

It is well known that device isolation regions are used to block carriers from freely flowing between devices through a substrate. Typically, the device isolation regions are formed between field effect transistors (FETs) in DRAMs to reduce current leakage created on field effect transistors. Traditionally, the device isolation regions are formed by LOCOS. Since LOCOS has increasingly matured, device isolation regions with a high reliability and efficiency can be formed with a low cost. However, the device isolation regions formed by LOCOS have the disadvantages of stress and a bird's beak surrounding each isolation region. In particular, the bird's beak leads to a poor isolation of each device isolation region in high-density ICs. Therefore, in high-density ICs, it is necessary to use a shallow trench isolation structure that can be easily reduced in size instead of the traditional isolation structure.

In a method of forming shallow trench isolation, trenches are first formed in a substrate by isotropic etching and then completely filled by oxide. Since the size of the formed shallow trench isolation regions can be reduced, bird's break encroachment caused by LOCOS can be prevented. Therefore, it is an ideal isolation method suitable for manufacturing CMOS in sub-micron processes.

FIGS. 1A-1F show a method of forming shallow trench isolation according to the prior art. Referring to FIG. 1A, a pad oxide layer 102 is first formed on a silicon substrate 100 by thermal oxidation, wherein the pad oxide layer 102 is used to protect the surface of the silicon substrate 100. Next, a silicon nitride layer 104, serving as a polishing stop layer, is formed on the pad oxide layer 102 by low pressure chemical vapor deposition (LPCVD).

Referring to FIG. 1B, a photoresist layer (not shown) is formed on the silicon nitride layer 104 by traditional photolithography and etching. Then, the silicon nitride layer 104, the pad oxide layer 102 and the silicon substrate 100 are etched in order, thereby forming a trench 106. The photoresist layer is removed.

Referring to FIG. 1C, a liner oxide layer 108 is formed on the inner surface of the trench 106 by thermal oxidation, wherein the liner oxide layer 108 extends to the top comers of the trench 106 to contact the pad oxide layer 102.

Referring to FIG. 1D, an insulating layer 110, such as a silicon oxide layer, is formed over the silicon substrate 100 and completely fills the trench 106 by, for example, atmospheric pressure chemical vapor deposition (APCVD). Thereafter, densification is performed on the insulating layer 110 at a high temperature.

Referring to FIG. 1E, using the silicon nitride layer 104 as a polishing stop layer, part of the insulating layer 110 above the level of the silicon nitride layer 104 is removed by chemical mechanical polishing (CMP), thereby forming a remaining insulating layer 110a in the trench 106.

Referring to FIG. 1F, the silicon nitride layer 104 is removed to expose the pad oxide layer 102. Then, the pad oxide layer 102 is removed by using a hydrofluoric acid (HF) solution thereby to form a field isolation region 110b.

In the prior method, when performing the densification on the insulating layer 110, the insulating layer 110 creates a mechanical stress on the silicon substrate 100, resulting in device failure.

### SUMMARY OF THE INVENTION

In view of the above, an object of the invention is to provide a method of forming shallow trench isolation. In the method, a flowable insulating layer, formed in a trench, can efficiently release a mechanical stress created on a substrate. Thus, device failure is completely eliminated.

The method of forming shallow trench isolation according to the invention includes the following steps. First, a pad oxide layer is formed on a substrate. A stop layer is formed on the pad oxide layer. Next, a trench is formed in the stop layer, the pad oxide layer and the substrate. A liner oxide layer is formed on the inner surface of the trench. Subsequently, a flowable insulating layer, such as a doped silicon oxide layer, is formed in the trench. An insulating layer, such as a silicon oxide layer, is formed in the trench on the flowable insulating layer. Finally, the stop layer and the pad oxide layer are removed so as to completely form a shallow trench isolation region.

### BRIEF DESCRIPTION OF THE DRAWINGS

The invention will be more fully understood from the detailed description given hereinbelow and the accompanying drawings which are given by way of illustration only, and thus do not limit the present invention, wherein:

FIGS. 1A-1F are schematic, cross-sectional views showing a method of forming traditional shallow trench isolation according to the prior art; and

FIGS. 2A-2H are schematic, cross-sectional views showing a method of forming shallow trench isolation according to a preferred embodiment of the invention.

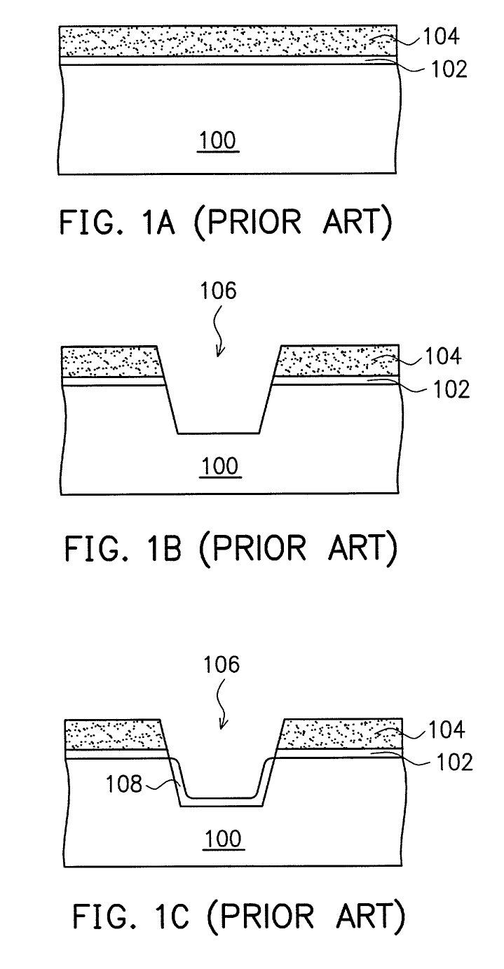

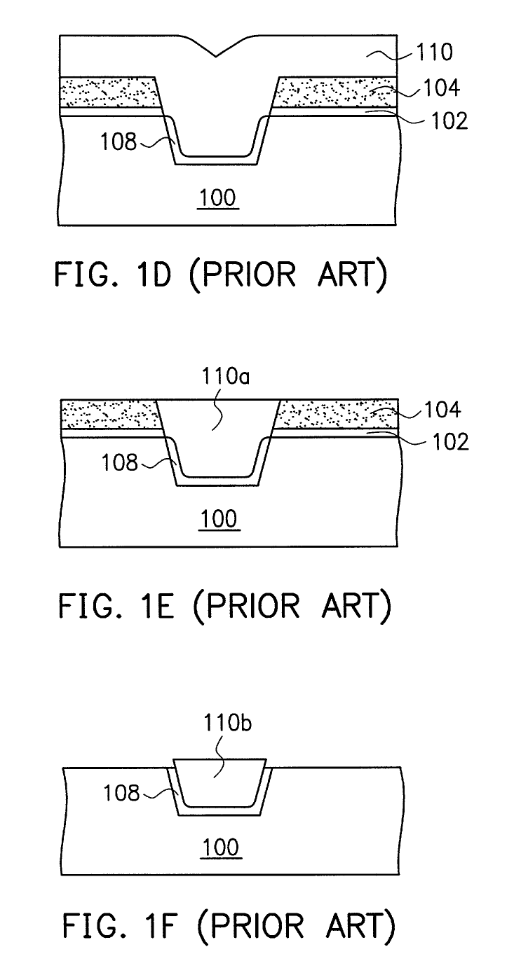

### DETAILED DESCRIPTION OF THE PREFERRED EMBODIMENTS

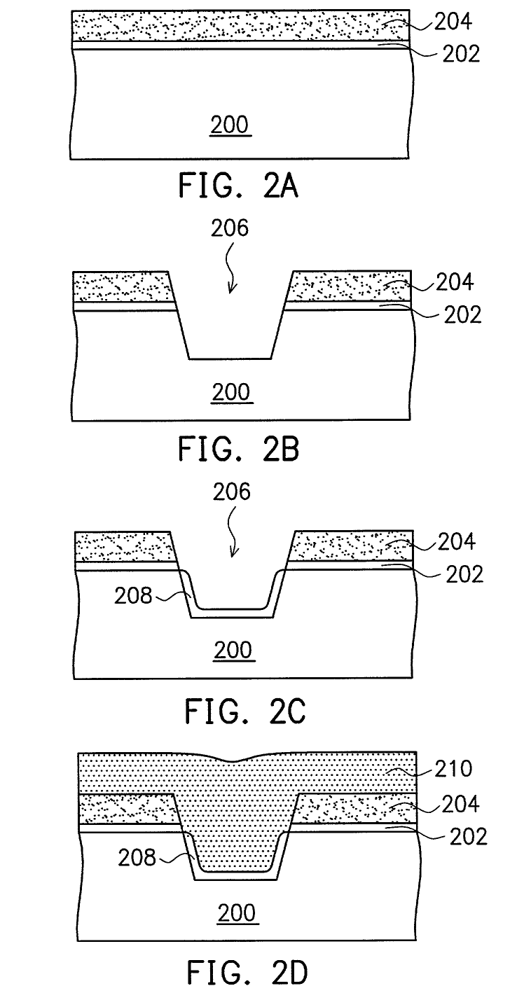

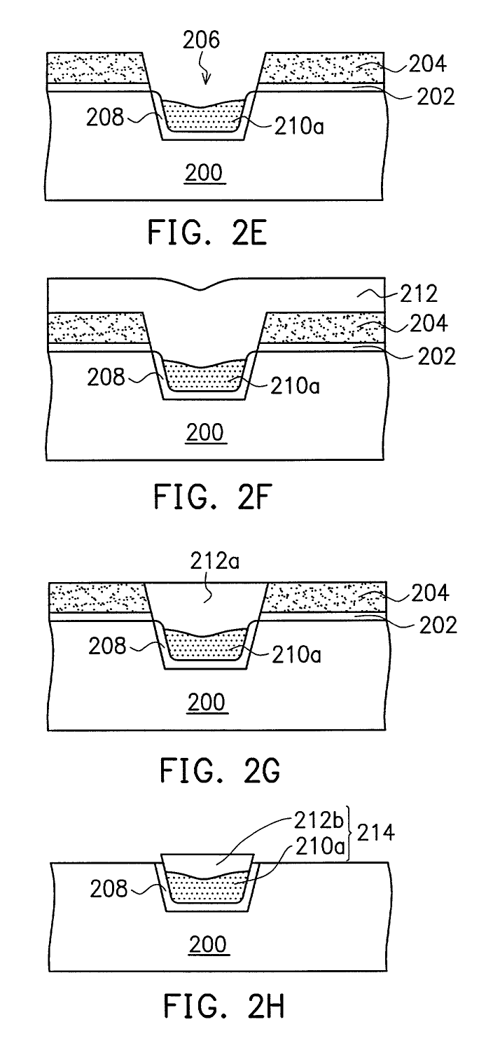

FIGS. 2A-2H show a method of forming shallow trench isolation according to a preferred embodiment of the invention.

Referring to FIG. 2A, a pad oxide layer 202 is first formed on a substrate 200, such as a silicon substrate, by, for example, thermal oxidation, wherein the pad oxide layer 202 is used to protect the surface of the substrate 200. Next, a stop layer 204, such as a silicon nitride layer, is formed on the pad oxide layer 202 by, for example, low pressure chemical vapor deposition (LPCVD).

Referring to FIG. 2B, a photoresist layer (not shown) is formed the stop layer 204 by traditional photolithography and etching. Then, the stop layer 204, the pad oxide layer 202 and the substrate 200 are etched in order by, for example, anisotropic etching, thereby forming a trench 206 with a depth in the range of 0.2-0.8 μm. Thereafter, the photoresist layer is removed.

Referring to FIG. 2C, a liner oxide layer 208, having a thickness of 100-1000 Å, is formed on the inner surface of the trench 206 by high-temperature thermal oxidation at a temperature in the range of 900-1,100° C. The liner oxide layer 208 extends to the top comers of the trench 206 to contact the pad oxide layer 202.

Referring to FIG. 2D, a flowable insulating layer 210, such as a flowable silicon oxide layer, having a thickness of 5,000-10,000 Å, is formed over the substrate 200 and completely fills the trench 206. The flowable silicon oxide layer has a better gap-filling capability than a general silicon oxide layer and can serve as a stress release buffer to release a mechanical stress created on the substrate in a subsequent process. Therefore, device failure can be completely eliminated.

Referring to FIG. 2E, the flowable insulating layer 210 has to be subjected to melt and flow processes because it still contains liquid and has an uneven surface. Thereafter, a curing process is performed on the flowable insulating layer 210 in a nitrogen (N₂) atmosphere at a temperature of 400° C.

Subsequently, part of the flowable insulating layer 210 is removed in order to form a remaining flowable insulating layer 210a and expose part of the liner oxide layer 208 by, for example, etch back, wherein the surface of the formed flowable insulating layer 210a is lower than that of the substrate 200. This step can prevent the flowable insulating layer 210a from exposing the substrate 200 and even remaining on a subsequently-formed gate after subsequent ion implanting.

Next, the remaining flowable insulating layer 210a is ion implanted with a dopant, such as boron or phosphorus, to prevent outgassing of a residual liquid remaining in the flowable insulating layer 210a as well as to harden the flowable insulating layer 210a.

Referring to FIG. 2F, an insulating layer 212, such as a doped silicon oxide layer, is formed over the substrate 200 and completely fills the trench 206 by, for example, atmospheric pressure chemical vapor deposition (APCVD). The insulating layer 212 can prevent the dopant contained in the flowable insulating layer 210a from diff-using to a subsequently-formed gate on the substrate 200 and even to a channel region.

Optionally, the insulating layer 212 can be densified by performing a densification process at a temperature in the range of 700-1,200° C.

Referring to FIG. 2G, the part of the insulating layer 212 above the level of the stop layer 204 is removed by, for example, chemical mechanical polishing, wherein the stop layer 204 serves as a polishing stop layer. As a result, only a remaining insulating layer 212a is formed in the trench 206 just on the remaining flowable insulating layer 210a.

Referring to FIG. 2H, the stop layer 204 and the pad oxide layer 202 are removed in sequence so as to completely form a field isolation region 214 which consists of the flowable insulating layer 210a and an insulating layer 212b. In general, the stop layer 204 is removed by wet etching using a phosphoric acid solution while the pad oxide layer 202 is removed by wet etching using a hydrofluoric (HF) acid solution.

In summary, the features of the invention are as follows:

(1) An insulating layer formed on a flowable insulating layer in a trench can prevent the dopant contained in the flowable insulating layer from diffusing to a subsequently-formed gate on a substrate and even to a channel region. The flowable insulating layer can efficiently release a mechanical stress exerted on the substrate, thereby eliminating a device failure.

(2) The method in accordance with the invention is compatible with all current semiconductor processes and is extremely suitable for manufacturer production arrangements.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming shallow trench isolation comprising:
providing a substrate;
forming a pad oxide layer on the substrate;
forming a stop layer on the pad oxide layer;
forming a trench in the stop layer, the pad oxide layer and the substrate;
forming a liner oxide layer on the inner surface of the trench;
forming a flowable insulating layer over the substrate, the flowable insulating layer completely filling the trench;
removing part of the flowable insulating layer until the liner oxide layer is exposed;
forming an insulating layer on the flowable insulating layer, the insulating layer completely filling the trench;
removing part of the insulating layer until the stop layer is exposed;
removing the stop layer; and
removing the pad oxide layer.

2. The method of forming shallow trench isolation as recited in claim 1, wherein the pad oxide layer is formed by thermal oxidation.

3. The method of forming shallow trench isolation as recited in claim 1, wherein the stop layer comprises a silicon nitride layer.

4. The method of forming shallow trench isolation as recited in claim 1, wherein the flowable insulating layer comprises a flowable silicon oxide layer.

5. The method of forming shallow trench isolation as recited in claim 1, wherein the insulating layer comprises a silicon oxide layer.

6. The method of forming shallow trench isolation as recited in claim 1, further comprising performing densification after the step of forming the insulating layer.

7. The method of forming shallow trench isolation as recited in claim 1, wherein the step of removing part of the flowable insulating layer comprises etch back.

8. The method of forming shallow trench isolation as recited in claim 1, wherein the step of removing part of the insulating layer comprises chemical mechanical polishing.

9. The method of forming shallow trench isolation as recited in claim 1, wherein the step of removing the stop layer comprises wet etching.

10. The method of forming shallow trench isolation as recited in claim 1, wherein the step of removing the pad oxide layer comprises wet etching.

11. A method of forming shallow trench isolation comprising:
providing a substrate;
forming a pad oxide layer on the substrate;
forming a stop layer on the pad oxide layer;
forming a trench in the stop layer, the pad oxide layer and the substrate;
forming a liner oxide layer on the inner surface of the trench;
forming a flowable insulating layer over the substrate, the flowable silicon oxide layer completely filling the trench;
removing part of the flowable silicon oxide layer until the liner oxide layer is exposed;
forming a silicon oxide layer on the flowable silicon oxide layer, the silicon oxide layer completely filling the trench;
removing part of the silicon oxide layer until the etching stop is exposed;
removing the stop layer; and
removing the pad oxide layer.

12. The method of forming shallow trench isolation as recited in claim 11, wherein the pad oxide layer is formed by thermal oxidation.

13. The method of forming shallow trench isolation as recited in claim 11, wherein the stop layer comprises a silicon nitride layer.

14. The method of forming shallow trench isolation as recited in claim 11, further comprising performing densification after the step of forming the silicon oxide layer.

15. The method of forming shallow trench isolation as recited in claim 11, wherein the step of removing part of the flowable silicon oxide layer comprises etch back.

16. The method of forming shallow trench isolation as recited in claim 11, wherein the step of removing part of the silicon oxide layer comprises chemical mechanical polishing.

17. The method of forming shallow trench isolation as recited in claim 11, wherein the step of removing the stop layer comprises wet etching.

18. The method of forming shallow trench isolation as recited in claim 11, wherein the step of removing the pad oxide layer comprises wet etching.

19. A method of forming shallow trench isolation comprising:
providing a substrate;
forming a pad oxide layer on the substrate;
forming a stop layer on the pad oxide layer;
forming a trench in the stop layer, the pad oxide layer and the substrate;
forming a liner oxide layer on the inner surface of the trench;
forming a flowable insulating layer in the trench;
removing the stop layer; and
removing the pad oxide layer.

20. The method of forming shallow trench isolation as recited in claim 19, wherein the method of forming the pad oxide layer comprises thermal oxidation.

21. The method of forming shallow trench isolation as recited in claim 19, wherein the stop layer comprises a silicon nitride layer.

22. The method of forming shallow trench isolation as recited in claim 19, wherein the step of forming the flowable insulating layer comprises:
forming a flowable silicon oxide layer over the substrate, the flowable silicon oxide layer completely filling the trench;
removing part of the flowable silicon oxide layer until the liner oxide layer is exposed;
forming a silicon oxide layer on the flowable silicon oxide layer, the silicon oxide layer completely filling the trench; and
removing part of the silicon oxide layer until the stop layer is exposed.

23. The method of forming shallow trench isolation as recited in claim 22, wherein the step of removing part of the flowable silicon oxide layer comprises etch back.

24. The method of forming shallow trench isolation as recited in claim 22, wherein further comprising performing densification after the step of forming the silicon oxide layer.

25. The method of forming shallow trench isolation as recited in claim 22, wherein the step of removing part of the silicon oxide layer comprises chemical mechanical polishing.

26. The method of forming shallow trench isolation as recited in claim 19, wherein the step of removing the stop layer comprises wet etching.

27. The method of forming shallow trench isolation as recited in claim 19, wherein the step of the removing pad oxide layer comprises wet etching.
